(19) United States
(12) Patent Application Publication
(10) Pub. No.: US 2024/0421016 A1
(43) Pub. Date: Dec. 19, 2024

(54) SEMICONDUCTOR PACKAGE AND MANUFACTURING METHOD OF THE SAME

(71) Applicant: SAMSUNG ELECTRONICS CO.,LTD., Suwon-si (KR)

(72) Inventors: Jing Cheng LIN, Suwon-si (KR); Jihwan SUH, Suwon-si (KR); Hyunchul JUNG, Suwon-si (KR); Youngkun JEE, Suwon-si (KR)

(73) Assignee: SAMSUNG ELECTRONICS CO.,LTD., Suwon-si (KR)

(21) Appl. No.: 18/667,269

(22) Filed: May 17, 2024

(30) Foreign Application Priority Data
Jun. 19, 2023 (KR) 10-2023-0078355

(51) Int. Cl. H01L 23/31; H01L 23/00; H01L 23/48; H01L 25/18

(52) U.S. Cl. CPC H01L 23/3128; H01L 23/481; H01L 24/08; H01L 24/32; H01L 25/18; H01L 24/80; H01L 2224/08145; H01L 2224/32145; H01L 2224/80895; H01L 2224/80896; H01L 2225/06541; H01L 2924/1815

(57) ABSTRACT

A semiconductor package includes a first semiconductor chip, second semiconductor chips stacked on the first semiconductor chip, a first molding layer, a dummy chip and a second molding layer. Each second semiconductor chip includes a semiconductor substrate comprising an active surface and an inactive surface opposite to the active surface. The first molding layer surrounds a portion of an upper surface of the first semiconductor chip and side surfaces of the second semiconductor chips and includes a trench that extends from an upper surface of the first molding layer into the first molding layer. The dummy chip is stacked on an uppermost second semiconductor chip of the second semiconductor chips. The second molding layer surrounds side surfaces of the dummy chip, and covers the first molding layer.

### CROSS-REFERENCE TO RELATED APPLICATION

This application is based on and claims priority under 35 U.S.C. § 119 to Korean Patent Application No. 10-2023-0078355, filed on Jun. 19, 2023 in the Korean Intellectual Property office, the disclosure of which being incorporated by reference herein in its entirety.

### BACKGROUND

Apparatuses, devices and methods consistent with the present disclosure relate to a semiconductor package and a manufacturing method of the semiconductor package, and more particularly, to a semiconductor package including stacked semiconductor chips and a manufacturing method of the semiconductor package.

As electronic products are required to be miniaturized, to have large capacity, and to have high performance, there is also a demand for high integration and high speed of semiconductor packages. To this end, semiconductor packages including a plurality of semiconductor chips including stacked semiconductor chips have been developed.

### SUMMARY

It is an aspect to provide a semiconductor package including stacked semiconductor chips and having improved structural reliability, and a manufacturing method of the semiconductor package.

It is another aspect to provide a semiconductor package having improved heat dissipation performance and a manufacturing method of the semiconductor package.

According to an aspect of one or more embodiments, there is provided a semiconductor package comprising a first semiconductor chip; a plurality of second semiconductor chips stacked on the first semiconductor chip, each of the plurality of second semiconductor chips including a semiconductor substrate comprising an active surface and an inactive surface opposite to the active surface; a first molding layer surrounding a portion of an upper surface of the first semiconductor chip and side surfaces of the plurality of second semiconductor chips, the first molding layer including a trench that extends from an upper surface of the first molding layer into the first molding layer; a dummy chip stacked on an uppermost second semiconductor chip of the plurality of second semiconductor chips; and a second molding layer surrounding side surfaces of the dummy chip, and covering the first molding layer.

According to another aspect of one or more embodiments, there is provided a semiconductor package comprising a first semiconductor chip including a first semiconductor substrate comprising an active surface and an inactive surface opposite to the active surface; a plurality of second semiconductor chips stacked on the first semiconductor chip, each of the plurality of second semiconductor chips including a second semiconductor substrate comprising an active surface and an inactive surface opposite to the active surface of the second semiconductor substrate; a first molding layer surrounding a portion of an upper surface of the first semiconductor chip and side surfaces of the plurality of second semiconductor chips, the first molding layer including a trench that extends from an upper surface of the first molding layer into the first molding layer; a dummy chip stacked on an uppermost second semiconductor chip among the plurality of second semiconductor chips; and a second molding layer surrounding side surfaces of the dummy chip, filling the trench, and covering an upper surface of the first molding layer, wherein the plurality of second semiconductor chips are stacked with the active surface of the second semiconductor substrate of each of the plurality of second semiconductor chips facing the first semiconductor chip.

According to yet another aspect of one or more embodiments, there is provided a semiconductor package comprising a first semiconductor chip including a first semiconductor substrate comprising an active surface and an inactive surface opposite to the active surface, and a plurality of first through electrodes configured to penetrate the first semiconductor substrate; a plurality of second semiconductor chips stacked on the first semiconductor chip, each of the plurality of second semiconductor chips including a second semiconductor substrate comprising an active surface and an inactive surface opposite to the active surface of the second semiconductor substrate; a first molding layer including a trench that surrounds side surfaces of the plurality of second semiconductor chips and extends from an upper surface of the first molding layer into the first molding layer, the first molding layer including a first side surface and a second side surface opposite to the first side surface; a dummy chip stacked on the plurality of second semiconductor chips, the dummy chip having a horizontal area identical to a horizontal area of each of the plurality of second semiconductor chips and having a height greater than a height of each of the plurality of second semiconductor chips; a second molding layer surrounding side surfaces of the dummy chip, filling the trench, and covering the first molding layer; a package redistribution layer under a lower surface of the first semiconductor chip; and a plurality of package connection terminals electrically connected to the package redistribution layer, wherein at least one of the plurality of second semiconductor chips comprises a plurality of second through electrodes configured to penetrate the second semiconductor substrate of the at least one of the plurality of second semiconductor chips, wherein the trench is arranged at a periphery of an uppermost surface of the first molding layer, wherein the first side surface of the first molding layer includes a side surface of the first molding layer that is exposed to an outside of the semiconductor package, and the second side surface of the first molding layer includes a side surface that is in contact with the plurality of second semiconductor chips, and wherein a height of the first side surface of the first molding layer is less than a height of the second side surface of the first molding layer.

### BRIEF DESCRIPTION OF THE DRAWINGS

Various embodiments will be more clearly understood from the following detailed description taken in conjunction with the accompanying drawings, in which:

FIG. 1 is a schematic cross-sectional view of a semiconductor package according to an embodiment;

FIG. 2 is an enlarged cross-sectional view of region II in FIG. 1;

FIG. 3 is an enlarged cross-sectional view of region III in FIG. 1;

FIGS. 4 through 6 are enlarged cross-sectional views of region II in FIG. 1 of semiconductor packages, according to some embodiments;

FIG. 7 is a schematic cross-sectional view of a semiconductor package according to an embodiment;

FIG. 8 is a flowchart of a manufacturing method of a semiconductor package, according to an embodiment; and

FIGS. 9 through 19 are cross-sectional views illustrating a manufacturing method of a semiconductor package, according to some embodiments.

### DETAILED DESCRIPTION

Because various changes can be applied to the embodiments and accordingly, the embodiments can have various types, some embodiments are illustrated in the drawings and detailed descriptions thereof are provided. However, these illustrations and detailed descriptions are not intended to limit the embodiments to particular disclosure forms.

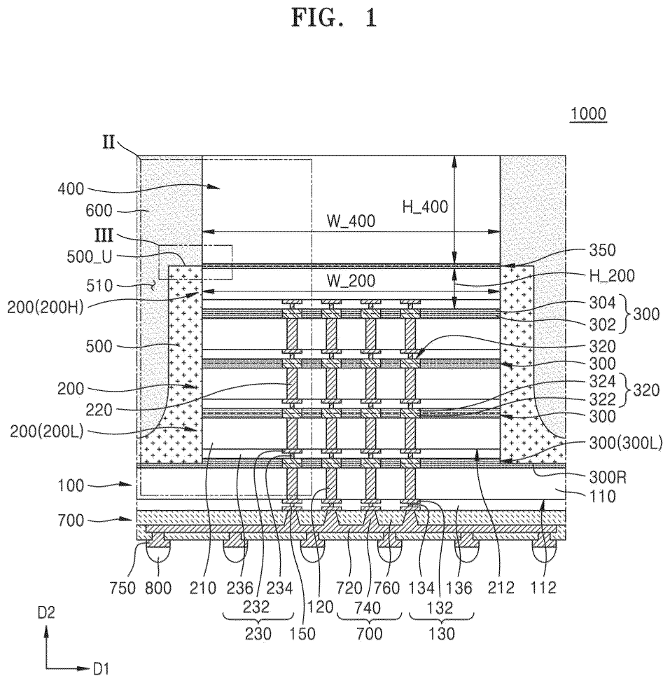

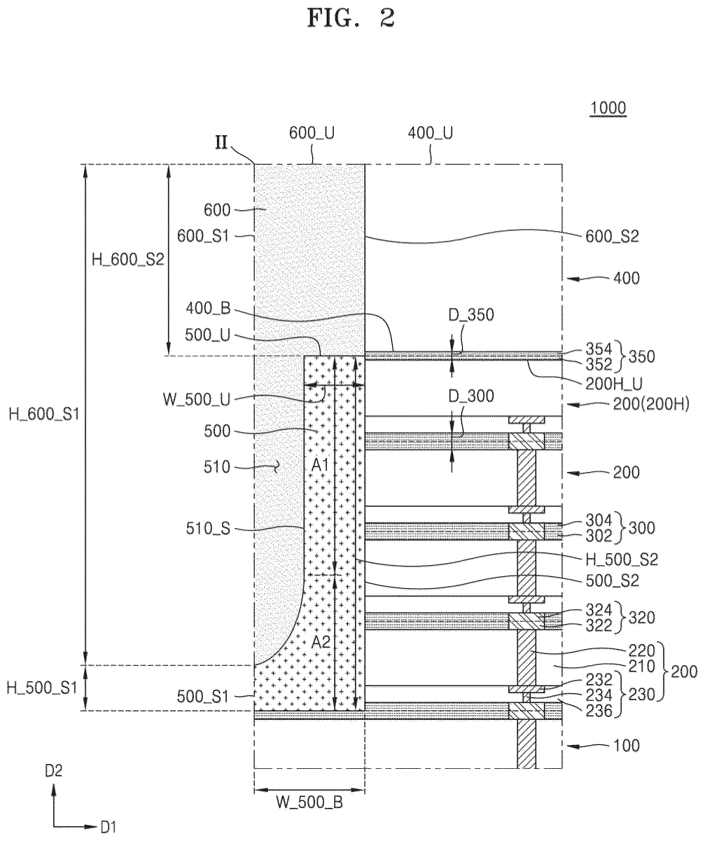

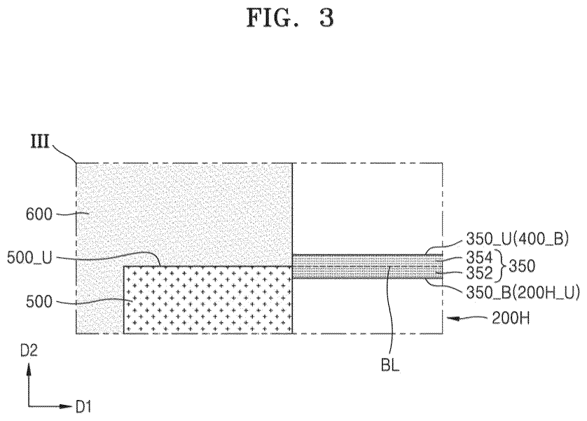

FIG. 1 is a schematic cross-sectional view of a semiconductor package 1000 according to an embodiment. FIG. 2 is an enlarged cross-sectional view of region II in FIG. 1. FIG. 3 is an enlarged cross-sectional view of region III in FIG. 1.

Referring to FIGS. 1 through 3, the semiconductor package 1000 may include a first semiconductor chip 100, a plurality of second semiconductor chips 200, a dummy chip 400, a first molding layer 500, and a second molding layer 600. In some embodiments, the semiconductor package 1000 may further include a plurality of bonding pads 320, a chip bonding insulating layer 300, and a support bonding insulating layer 350.

Although in FIG. 1 the semiconductor package 1000 is illustrated including four second semiconductor chips 200, the embodiment is not limited thereto. In some embodiments, the semiconductor package 1000 may include two or more second semiconductor chips 200. In some embodiments, the semiconductor package 1000 may include a multiple of four second semiconductor chips 200.

The plurality of second semiconductor chips 200 may be sequentially stacked on the first semiconductor chip 100. For convenience of description, the second semiconductor chip 200 at the lowest position of the plurality of second semiconductor chips 200 may be referred to as a lowermost second semiconductor chip 200L, and the second semiconductor chip 200 at the highest position of the plurality of second semiconductor chips 200 may be referred to as an uppermost second semiconductor chip 200H.

Hereinafter, unless particularly defined, a direction in parallel with an upper surface of the first semiconductor chip 100 may be defined as a horizontal direction D1, and a direction perpendicular to the upper surface of the first semiconductor chip 100 may be defined as a vertical direction D2.

The first semiconductor chip 100 may include a first semiconductor substrate 110 having an active surface and an inactive surface, which are opposite to each other, a first semiconductor element 112 formed on the active surface of the first semiconductor substrate 110, a first distribution structure 130 formed on the active surface of the first semiconductor substrate 110, and a plurality of first through electrodes 120 connected to the first distribution structure 130 and penetrating at least a portion of the first semiconductor chip 100.

In the semiconductor package 1000, the first semiconductor chip 100 may be arranged so that the active surface of the first semiconductor substrate 110 faces a lower side, and the inactive surface thereof the first semiconductor substrate 110 faces an upper side. Accordingly, unless particularly described otherwise, the upper surface of the first semiconductor chip 100 included in the semiconductor package 1000 may be referred to as a side, toward which the inactive surface of the first semiconductor substrate 110 faces, and the lower surface of the first semiconductor chip 100 may be referred to as a side toward which the active surface of the first semiconductor substrate 110 faces. However, when descriptions are given with the first semiconductor chip 100 as a reference, the lower surface of the semiconductor chip 100 facing toward the active surface of the first semiconductor substrate 110 may be referred to as a front surface of the first semiconductor chip 100, and the upper surface of the first semiconductor chip 100 facing the inactive surface of the first semiconductor substrate 110 may be referred to as a rear surface of the first semiconductor chip 100.

Each of the plurality of second semiconductor chips 200 may include a second semiconductor substrate 210 having an active surface and an inactive surface, which are opposite to each other, a second semiconductor device 212 formed on the active surface of the second semiconductor substrate 210, and a second distribution structure 230 formed on the active surface of the second semiconductor substrate 210.

Each of the plurality of second semiconductor chips 200 except for the uppermost second semiconductor chip 200H may further include a plurality of second through electrodes 220 connected to the second distribution structure 230 and penetrating at least a portion of the second semiconductor chip 200. Among the plurality of second semiconductor chips 200, the uppermost second semiconductor chip 200H arranged farthest from the first semiconductor chip 100 may not include the plurality of second through electrodes 220. However, embodiments are not limited thereto and, in some embodiments, the uppermost second semiconductor chip 200H may also include the plurality of second through electrodes 220.

In some embodiments, a length according to a thickness H_200 in the vertical direction D2 of each of the plurality of second semiconductor chips 200 may be 20 μm to 80 μm. The thickness H_200 of each of the plurality of second semiconductor chips 200 may have substantially the same value.

In the semiconductor package 1000, each of the plurality of second semiconductor chips 200 may be sequentially stacked on the first semiconductor chip 100 in the vertical direction while the active surface of each of the plurality of second semiconductor chips 200 faces toward the lower side, i.e., toward the first semiconductor chip 100. Accordingly, unless particularly described otherwise, the upper surface of the second semiconductor chip 200 may be referred to as a side, toward which the inactive surface of the second semiconductor substrate 210 faces, and the lower surface of the second semiconductor chip 200 may be referred to as a side toward which the active surface of the second semiconductor substrate 210 faces. However, when descriptions are given with the second semiconductor chip 200 as a reference, the lower surface of the second semiconductor chip 200 facing toward the active surface of the second semiconductor substrate 210 may be referred to as the front surface of the second semiconductor chip 200, and the upper surface of the second semiconductor chip 200 facing the inactive surface of the second semiconductor substrate 210 may be referred to as the rear surface of the second semiconductor chip 200.

In some embodiments, the first semiconductor substrate 110 and the second semiconductor substrate 210 may include, for example, a semiconductor material such as silicon (Si). In some embodiments, the first semiconductor substrate 110 and the second semiconductor substrate 210 may include a semiconductor material such as germanium (Ge).

Each of the first semiconductor substrate 110 and the second semiconductor substrate 210 may have an active surface and an inactive surface opposite to the active surface. The first semiconductor substrate 110 and the second semiconductor substrate 210 may include a conductive region, for example, a well that is doped with impurities. The first semiconductor substrate 110 and the second semiconductor substrate 210 may have various device isolation structures such as a shallow trench isolation (STI) structure or a deep trench isolation (DTI) structure.

Each of the first semiconductor element 112 and the second semiconductor element 212 may include a plurality of individual devices of various types. The plurality of individual devices may include various microelectronic devices, for example, a metal-oxide-semiconductor field effect transistor (MOSFET) such as a complementary metal-oxide-semiconductor (CMOS) transistor, an image sensor, such as a system large scale integration (LSI) sensor and a CMOS imaging sensor (CIS), a micro-electro-mechanical system (MEMS), an active device, or a passive device, etc.

The plurality of individual devices may be electrically connected to the conductive region of the first semiconductor substrate 110 or the second semiconductor substrate 210. Each of the first semiconductor device 112 and each of the second semiconductor device 212 may further include at least two of the plurality of individual devices, or a conductive wiring or a conductive plug electrically connecting the plurality of individual devices to the conductive region of each of the first semiconductor substrate 110 and the second semiconductor substrate 210. In some embodiments, each of the plurality of individual devices may be electrically isolated from other adjacent individual devices by an insulating layer.

At least one of the first semiconductor chip 100 and the second semiconductor chip 200 may include a memory semiconductor chip. In some embodiments, the first semiconductor chip 100 may include a buffer chip including a serial-parallel conversion circuit and for controlling the plurality of second semiconductor chips 200, and the plurality of second semiconductor chips 200 may include a memory chip including memory cells.

For example, the semiconductor package 1000 including the first semiconductor chip 100 and the plurality of second semiconductor chips 200 may include high bandwidth memory (HBM), the first semiconductor chip 100 may be referred to as an HBM controller die, and each of the plurality of second semiconductor chips 200 may be referred to as a dynamic random access memory (RAM) (DRAM) die.

Surface roughness may be referred to as a size of fine irregularities that occur on the surface of an object. In the process of molding and cutting an object, a number of small and non-uniform irregularities may occur on the surface of the object. A calculated value of the size of the irregularities may be expressed as a surface roughness.

For example, after a centerline of a surface on a cross-section of the object is marked, a mean line may be shown by calculating an area of deviation of an unevenness of the object from the centerline based on the centerline of the surface, and calculating a mean in length units of the center line. The difference between the center line and the mean line shown in this manner may be defined as the center line mean roughness. In other words, the center line mean roughness may be expressed as a value obtained by dividing a line (i.e., the mean line), which is smoothened by cutting existing mountains and filling valleys within a certain measurement length, by the certain measurement length. In this case, the center line may become a standard for distinguishing mountains from valleys. The centerline mean roughness may be one of the methods of expressing the surface roughness. The unit of surface roughness may be micrometer or nanometer.

The mean roughness may also be expressed as a 10-point mean roughness.

Hereinafter, the surface roughness may be described based on the center line mean roughness but embodiments are not limited thereto and, in some embodiments, the surface roughness may be based on the 10-point mean roughness.

The surface roughness of an upper surface 200H_U of the uppermost second semiconductor chip 200H among the plurality of second semiconductor chips 200 may be 0.1 nm to 6 nm. In detail, when the uppermost second semiconductor chip 200H further includes the upper surface chip bonding insulating material layer 352 (see FIGS. 2-3), the surface roughness of the upper surface of the upper surface chip bonding insulating material layer 352 may be 0.1 nm to 6 nm. For example, by removing an upper portion of the uppermost second semiconductor chip 200H by using a chemical mechanical polishing (CMP) process, the surface roughness of the upper surface 200H_U of the uppermost second semiconductor chip 200H may be reduced. In some embodiments, the surface roughness of the upper surface 200H_U of the uppermost second semiconductor chip 200H may be 5 nm.

As the plurality of second semiconductor chips 200 are sequentially stacked on the first semiconductor chip 100, the surface uniformity of the second semiconductor chip 200, which is arranged far away from the first semiconductor chip 100 among the plurality of second semiconductor chips 200, may be worsened. In some embodiments, in the semiconductor package 1000, by using a CMP process, the surface uniformity of the upper surface 200H_U of the uppermost second semiconductor chip 200H may be improved, and thus, the bonding strength between the uppermost second semiconductor chip 200H and the dummy chip 400 may be improved. For example, by improving the surface uniformity of the upper surface 200H_U of the uppermost second semiconductor chip 200H, a direct oxide bonding may be applied between the dummy chip 400 and the uppermost second semiconductor chip 200H.

Returning to FIG. 1, the first distribution structure 130 may include a plurality of first distribution patterns 132, a plurality of first distribution vias 134 connected to the plurality of first distribution patterns 132, and a first inter-distribution insulating layer 136 surrounding the plurality of first distribution patterns 132 and the plurality of first distribution vias 134. In some embodiments, the first distribution structure 130 may have a multi-layer distribution structure including the first distribution patterns 132 and the first distribution vias 134 at different vertical levels.

In some embodiments, the first semiconductor chip 100 may further include a plurality of chip pads 150. The plurality of chip pads 150 may be arranged under the lower surface of the first semiconductor chip 100, and may be electrically connected to the first distribution pattern 132 and/or the first distribution via 134. The plurality of chip pads 150 may be electrically connected to the first semiconductor device 112 or the first distribution structure 130 via the first distribution pattern 132 and the first distribution via 134.

The second distribution structure 230 may include a plurality of second distribution patterns 232, a plurality of second distribution vias 234 connected to the plurality of second distribution patterns 232, and a second inter-distribution insulating layer 236 surrounding the plurality of second distribution patterns 232 and the plurality of second distribution vias 234. In some embodiments, the second distribution structure 230 may have a multi-layer distribution structure including the second distribution patterns 232 and the second distribution vias 234 at different vertical levels.

The plurality of first distribution patterns 132, the plurality of first distribution vias 134, the plurality of second distribution patterns 232, and the plurality of second distribution vias 234 may include a metal material, for example, aluminum, copper, or tungsten. In some embodiments, the plurality of first distribution patterns 132, the plurality of first distribution vias 134, the plurality of second distribution patterns 232, and the plurality of second distribution vias 234 may include distribution-purpose barrier layers and distribution-purpose metal layers. The distribution-purpose barrier layer may include a metal, metal nitride, or an alloy. The distribution-purpose metal layer may include at least one metal of W, Al, Ti, Ta, Ru, Mn, and Cu.

When the first distribution structure 130 and the second distribution structure 230 have a multi-layer distribution structure, the first inter-distribution insulating layer 136 and the second inter-distribution insulating layer 236 may have a multi-layer structure, in which a plurality of insulating layers are stacked in response to a multi-layer distribution structure of the first distribution structure 130 and the second distribution structure 230. For example, the first inter-distribution insulating layer 136 and the second inter-distribution insulating layer 236 may include silicon oxide, silicon nitride, or silicon oxynitride, or an insulation material having a lower dielectric constant than silicon oxide, or a bonding thereof. In some embodiments, the first inter-distribution insulating layer 136 and the second inter-distribution insulating layer 236 may include a tetraethyl orthosilicate (TEOS) film or an ultra low dielectric constant (ULK) film having an ultra low dielectric constant K of about 2.2 to about 2.4. The ULK film may include a SiOC film or a SiCOH film.

Each of the first through electrode 120 and the second through electrode 220 may include a through silicon via (TSV). Each of the first through electrode 120 and the second through electrode 220 may include a conductive plug penetrating each of the first semiconductor substrate 110 and the second semiconductor substrate 210, and a conductive barrier layer surrounding the conductive plug. A via insulating layer may be arranged between the first through electrode 120 and the first semiconductor substrate 110, and between the second through electrode 220 and the second semiconductor substrate 210, and may surround the sidewalls of the first through electrode 120 and the second through electrode 220.

The dummy chip 400 of the semiconductor package 1000 may be stacked on the uppermost second semiconductor chip of the plurality of second semiconductor chips 200. In other words, the dummy chip 400 may be stacked on the uppermost second semiconductor chip 200H. In some embodiments, the dummy chip 400 may include, for example, a semiconductor material such as silicon (Si). In some embodiments, the dummy chip 400 may include only a semiconductor material. For example, in some embodiments, the dummy chip 400 may include a portion of a bare wafer.

In some embodiments, a length in the vertical direction D2 of the dummy chip 400, i.e., a thickness H_400, may be greater than the thickness H_200 of each of the plurality of second semiconductor chips 200. The thickness H_400 of the dummy chip 400 may be 100 μm to 500 μm.

In some embodiments, a horizontal area W_400 of the dummy chip 400 may be substantially the same as a horizontal area W_200 of each of the plurality of second semiconductor chips 200. For example, the horizontal width W_400 of the dummy chip 400, i.e., the length of the dummy chip 400 in the horizontal direction D1, may be substantially the same as a horizontal width of the uppermost second semiconductor chip 200H in the horizontal direction D1. The dummy chip 400 may completely cover the upper surface 200H_U of the uppermost second semiconductor chip 200H, and may be stacked on the uppermost second semiconductor chip 200H.

Although FIG. 1 illustrates that the semiconductor package 1000 includes one dummy chip 400, the number of dummy chips 400 is not limited thereto. In some embodiments, the number of dummy chips 400 may be two or more.

The first molding layer 500 of the semiconductor package 1000 may surround a portion of the upper surface of the first semiconductor chip 100, and may surround side surfaces of a plurality of second semiconductor chips 200. In other words, the first molding layer 500 may surround a region of the upper surface of the first semiconductor chip 100, in which the plurality of second semiconductor chips 200 are not disposed.

The first molding layer 500 may include a trench 510 extending from an upper surface to the inside thereof. In other words, the trench 510 may extend from an upper surface of the first molding layer 500 into the first molding layer 500. A surface 510_S forming the trench 510 may extend from a corner of an uppermost surface 500_U of the first molding layer 500 to a corner of a side surface of the first molding layer 500 exposed to the outside of the semiconductor package 1000. In other words, the trench 510 may be at the edge of the uppermost surface 500_U of the first molding layer 500.

Hereinafter, the uppermost surface 500_U of the first molding layer 500 may be referred to as a region of the upper surface of the first molding layer 500 in which the trench 510 is not arranged. In other words, the uppermost surface 500_U of the first molding layer 500 may be referred to as a region of the first molding layer 500 that is farthest from the first semiconductor chip 100.

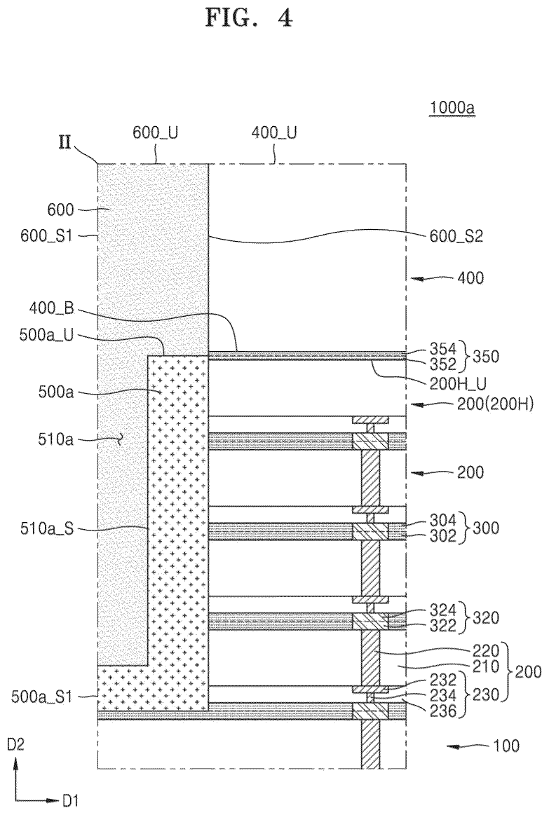

In some embodiments, the trench 510 of the first molding layer 500 may have a constant horizontal width at an upper portion A1 thereof, and may have a horizontal width that decreases toward the first semiconductor chip 100 at a lower portion A2 thereof. In some embodiments, a surface forming the trench 510 of the first molding layer 500 may include a curved surface portion in which an inner horizontal width of the trench 510 is decreased. For example, the surface 510_S forming the trench 510 of the first molding layer 500 may have a “J” shape in a cross-section of the first molding layer 500. In FIG. 1, the shape of the trench 510 is illustrated as a “J” shape but embodiments are not limited thereto. Other shapes of the trench 510 are described below with reference to FIGS. 4 through 6.

In the process of forming the first molding layer 500 of the semiconductor package 1000, a thermal expansion rate of the first molding layer 500 may be different from a thermal expansion rate of the plurality of second semiconductor chips 200, and thus a warpage phenomenon occurring in the semiconductor package 1000 may be reduced by forming the trench 510. In other words, in the process of forming the trench 510 by removing a portion of the first molding layer 500, the degree of bending of the plurality of second semiconductor chips 200 may be reduced.

The second molding layer 600 of the semiconductor package 1000 may surround side surfaces of the dummy chip 400, and may cover the first molding layer 500. The second molding layer 600 may fill the inside of the trench 510. In other words, a portion of a lower surface of the second molding layer 600 may correspond to the surface 510_S of the trench 510.

In some embodiments, the second molding layer 600 may be spaced apart from the first semiconductor chip 100 in the vertical direction D2 with the first molding layer 500 therebetween. In some embodiments, the second molding layer 600 may be spaced apart from the plurality of second semiconductor chips 200 in the horizontal direction D1 with the first molding layer 500 therebetween. For example, a portion of the second molding layer 600 arranged in the trench 510 of the first molding layer 500 may be spaced apart from the first semiconductor chip 100 and the plurality of second semiconductor chips 200 with the first molding layer 500 therebetween.

In some embodiments, the first molding layer 500 and the second molding layer 600 may include an epoxy mold compound (EMC). In some embodiments, composition materials of the first molding layer 500 and the second molding layer 600 may be the same. However, although the composition materials of the first molding layer 500 and the second molding layer 600 are the same, the curing time of the first molding layer 500 may be different from the curing time of the second molding layer 600, and thus, there may be a boundary between the first molding layer 500 and the second molding layer 600. In other words, after the first molding layer 500 is cured and an interval has passed, the second molding layer 600 may be cured, and there may be a boundary surface between the first molding layer 500 and the second molding layer 600. The boundary surface between the first molding layer 500 and the second molding layer 600 may be coplanar with the surface 510_S forming the trench 510 of the first molding layer 500. In some embodiments, the boundary may be visible.

Referring to FIG. 2, a bonding method between the plurality of second semiconductor chips 200, a bonding method between the first semiconductor chip 100 and the lowermost second semiconductor chip 200L, and a bonding method between the uppermost second semiconductor chip 200H and the dummy chip 400 are described in detail below.

The semiconductor package 1000 may further include the plurality of bonding pads 320 and a plurality of chip bonding insulating layers 300.

The plurality of bonding pads 320 may be arranged between the plurality of second semiconductor chips 200 and between the first semiconductor chip 100 and the lowermost second semiconductor chip 200L, and may electrically connect the plurality of second semiconductor chips 200 to each other and may electrically connect the first semiconductor chip 100 to the lowermost second semiconductor chip 200L.

The second distribution pattern 232 and/or the second distribution via 234 of the second distribution structure 230 of the second semiconductor chip 200 except for the lowermost second semiconductor chip 200L may be electrically connected to a plurality of second through electrodes 220 of the other second semiconductor chip 200. The second distribution pattern 232 and/or the second distribution via 234 of the second distribution structure 230 of the lowermost second semiconductor chip 200L may be electrically connected to the plurality of first through electrodes 120 included in the first semiconductor chip 100 at a lower side of the second distribution pattern 232 and/or the second distribution via 234 via the plurality of bonding pads 320.

The plurality of chip bonding insulating layers 300 may be between each of the plurality of second semiconductor chips 200 and between the first semiconductor chip 100 and the lowermost second semiconductor chip 200L, and may surround the plurality of bonding pads 320. In other words, the plurality of chip bonding insulating layers 300 may be between adjacent ones of the plurality of second semiconductor chips 200.

In some embodiments, a lowermost chip bonding insulating layer 300L may have a first recess 300R in an upper portion thereof, so that a thickness of a portion of the lowermost chip bonding insulating layer 300L that overlaps the lowermost second semiconductor chip 200L in the vertical direction is greater than a thickness of a portion of the lowermost chip bonding insulating layer 300L that does not overlap the lowermost second semiconductor chip 200L in the vertical direction. In other words, the first recess 300R may be arranged at a portion where a portion of the lowermost chip bonding insulating layer 300L does not overlap the lowermost second semiconductor chip 200L in the vertical direction D2.

The lowermost chip bonding insulating layer 300L may entirely cover a portion of the upper surface of the first semiconductor chip 100 which does not overlap the lowermost second semiconductor chip 200L in the vertical direction D2. A portion of the upper surface of the first semiconductor chip 100 overlapping the lowermost second semiconductor chip 200L in the vertical direction D2, and a portion of the lower surface of the lowermost second semiconductor chip 200L may be covered by the plurality of bonding pads 320, and the other portions of the lower surface of the lowermost second semiconductor chip 200L may be covered by the lowermost chip bonding insulating layer 300L.

The remaining chip bonding insulating layers 300 except for the lowermost chip bonding insulating layer 300L may cover, together with the plurality of bonding pads 320, both the upper surface and the lower surface of the second semiconductor chip 200 facing each other. The remaining chip bonding insulating layers 300 except for the lowermost chip bonding insulating layer 300L may have a flat upper surface and a flat lower surface to have a substantially same thickness.

After conductive material layers, for example, a plurality of upper surface chip connection pads 322 and a plurality of lower surface chip connection pads 324, are respectively formed on surfaces facing each other of two adjacent chips among the first semiconductor chip 100 and the plurality of second semiconductor chips 200, each of the plurality of bonding pads 320 may be formed by diffusion bonding, in which the upper surface chip connection pad 322 and the lower surface chip connection pad 324 facing each other contact by expansion due to heat, and become one body through diffusion of metal atoms included therein.

After insulating material layers, for example, an upper surface chip bonding insulating material layer 302 and a lower surface chip bonding insulating material layer 304, are respectively formed on surfaces facing each other of two adjacent chips among the first semiconductor chip 100 and the plurality of second semiconductor chips 200, the chip bonding insulating layer 300 may be formed, in a process of forming the plurality of bonding pads 320, by diffusion bonding, in which the upper surface chip bonding insulating material layer 302 and the lower surface chip bonding insulating material layer 304 facing each other contact by expansion due to heat, and become one body through diffusion of atoms included therein.

The lowermost chip bonding insulating layer 300L arranged between the first semiconductor chip 100 and the lowermost second semiconductor chip 200L among the plurality of chip bonding insulating layers 300 may be formed by diffusion bonding of an insulating material layer covering the upper surface of the first semiconductor chip 100 and an insulating material layer covering the lower surface of the lowermost second semiconductor chip 200L.

For example, a bonding method between the plurality of second semiconductor chips 200, which are bonded by the plurality of bonding pads 320 and the chip bonding insulating layer 300, and a bonding method between the first semiconductor chip 100 and the lowermost second semiconductor chip 200L may be referred to as hybrid bonding.

The semiconductor package 1000 may further include the support bonding insulating layer 350. The support bonding insulating layer 350 may be arranged between the uppermost second semiconductor chip 200H and the dummy chip 400. After insulating material layers, for example, the upper surface chip bonding insulating material layer 352 and a lower surface dummy bonding insulating material layer 354, are respectively formed on the upper surface of the uppermost second semiconductor chip 200H and a lower surface 400_B of the dummy chip 400 facing each other, the support bonding insulating layer 350 may be formed by diffusion bonding, in which insulating material layers facing each other contact by expansion due to heat, and become one body through diffusion of atoms included in the insulating material layers.

The support bonding insulating layer 350 may cover the lower surface 400_B of the dummy chip 400 (see FIG. 2). A lower surface 350_B of the support bonding insulating layer 350 may cover the upper surface 200H_U of the uppermost second semiconductor chip 200H (see FIG. 3). For example, the uppermost second semiconductor chip 200H and the dummy chip 400 may be bonded only by using the support bonding insulating layer 350. In some embodiments, when the uppermost second semiconductor chip 200H includes the plurality of second gate electrodes 220, the support bonding insulating layer 350 may cover the plurality of second gate electrodes 220 which are exposed to an upper surface of the second semiconductor substrate 210 of the uppermost second semiconductor chip 200H and to an upper surface of the second semiconductor substrate 210 of the uppermost second semiconductor chip 200H.

For example, the bonding method between the uppermost second semiconductor chip 200H and the dummy chip 400, which are bonded only by using the support bonding insulating layer 350, may be referred to as direct oxide bonding.

In some embodiments, a thickness D_300 of each of the plurality of chip bonding insulating layers 300 may be greater than a thickness D_350 of the support bonding insulating layer 350 (see FIG. 2). For example, each of the plurality of chip bonding insulating layers 300 may be inside each of the plurality of bonding pads 320, and accordingly, the thickness D_300 of each of the plurality of chip bonding insulating layers 300 may be the same as the thickness of each of the plurality of bonding pads 320. However, because the support bonding insulating layer 350 does not include a bonding pad therein, the thickness D_350 of the support bonding insulating layer 350 may be less than the thickness D_300 of each of the plurality of chip bonding insulating layers 300.

The chip bonding insulating layer 300 and the support bonding insulating layer 350 may include any one material of SiO, SiN, SiCN, SiCO, and a polymer material. The polymer material may include benzocyclobutene (BCB), polyimide (PI), polybenzoxazole (PBO), silicone, acrylate, or epoxy. For example, in some embodiments, the chip bonding insulating layer 300 and the support bonding insulating layer 350 may include silicon oxide. In some embodiments, the chip bonding insulating layer 300 and the support bonding insulating layer 350 may include the same material.

The first molding layer 500 and the second molding layer 600 are described in more detail with reference to FIGS. 2 and 3.

The first molding layer 500 may include a first side surface 500_S1 and a second side surface 500_S2 opposite to each other. The first side surface 500_S1 of the first molding layer 500 may include a side surface exposed to the outside of the semiconductor package 1000, and the second side surface 500_S2 may include a side surface in contact with the plurality of second semiconductor chips 200.

In some embodiments, a length in the vertical direction D2 of the first side surface 500_S1 of the first molding layer 500, i.e., a height H_500_S1, may be less than a length in the vertical direction D2 of the second side surface 500_S2 of the first molding layer 500, i.e., a height H_500_S2. For example, because a portion of the first side surface 500_S1 of the first molding layer 500 is removed by the trench 510, the height H_500_S1 of the first side surface 500_S1 of the first molding layer 500 may be less than the height H_500_S2 of the second side surface 500_S2 of the first molding layer 500. In some embodiments, the height H_500_S1 of the first side surface 500_S1 of the first molding layer 500 may be less than the height H_500_S2 of the second side surface 500_S2 of the first molding layer 500 by an extension depth of the trench 510.

In some embodiments, the length in the horizontal direction D1 of the uppermost surface 500_U of the first molding layer 500, i.e., a horizontal width W_500_U, may be less than the length in the horizontal direction D1 of the lower surface of the first molding layer 500, i.e., a horizontal width W_500_B. For example, because a portion of the uppermost surface 500_U of the first molding layer 500 is removed by the trench 510, the horizontal width W_500_U of the uppermost surface 500_U of the first molding layer 500 may be less than the horizontal width W_500_B of the lower surface of the first molding layer 500. In some embodiments, the horizontal width W_500_U of the uppermost surface 500_U of the first molding layer 500 may be less than the horizontal width W_500_B of the lower surface of the first molding layer 500 by a horizontal width of the trench 510.

The term “vertical level” used in this specification may be referred to as a distance apart from the upper surface of the first semiconductor chip 100 in the vertical direction D2.

In some embodiments, when the uppermost second semiconductor chip 200H includes the upper surface chip bonding insulating material layer 352 arranged on the upper surface 200H_U of the uppermost second semiconductor chip 200H, a vertical level of the uppermost surface 500_U of the first molding layer 500 may be the same as a vertical level of the upper surface chip bonding insulating material layer 352. For example, the uppermost surface 500_U of the first molding layer 500 may be coplanar with the upper surface chip bonding insulating material layer 352. In this case, because the upper surface chip bonding insulating material layer 352 is thin, the vertical level of the uppermost surface 500_U of the first molding layer 500 may be substantially the same as a vertical level of the upper surface 200H_U of the uppermost second semiconductor chip 200H.

In some embodiments, the vertical level of the uppermost surface 500_U of the first molding layer 500 may be lower than a vertical level of an upper surface 350_U of the support bonding insulating layer 350, and may be higher than a vertical level of the lower surface 350_B of the support bonding insulating layer 350. In other words, the uppermost surface 500_U of the first molding layer 500 may be on one side of the support bonding insulating layer 350. Because the support bonding insulating layer 350 is formed by diffusion bonding of the upper surface chip bonding insulating material layer 352 and the lower surface dummy bonding insulating material layer 354, a vertical level of a bonded surface BL, in which the upper surface chip bonding insulating material layer 352 is bonded with the lower surface dummy bonding insulating material layer 354, may be the same as the vertical level of the uppermost surface 500_U of the first molding layer 500 (see, e.g., FIG. 3). For example, the bonded surface BL may be substantially the same as the upper surface of the upper surface chip bonding insulating material layer 352.

In some embodiments, in the semiconductor package 1000, upper portions of the first molding layer 500 and the uppermost second semiconductor chip 200H may be removed by using a CMP process, the dummy chip 400 may be stacked on the uppermost second semiconductor chip 200H, and thus, the vertical level of the uppermost surface 500_U of the first molding layer 500 may be the same as the vertical level of the upper surface 200H_U of the uppermost second semiconductor chip 200H. When the uppermost second semiconductor chip 200H is bonded to the dummy chip 400 by using a direct oxide bonding, upper portions of the first molding layer 500 and the uppermost second semiconductor chip 200H may be removed in a state, in which the upper surface of the uppermost second semiconductor chip 200H includes the upper surface chip bonding insulating material layer 352, and thus, the vertical level of the uppermost surface 500_U of the first molding layer 500 may be the same as the vertical level of the upper surface of the upper surface chip bonding insulating material layer 352.

The second molding layer 600 may include a first side surface 600_S1 and a second side surface 600_S2 opposite to each other. The first side surface 600_S1 of the second molding layer 600 may be exposed to the outside of the semiconductor package 1000, and the second side surface 600_S2 of the second molding layer 600 may be in contact with the side surface of the dummy chip 400.

In some embodiments, a height H_600_S1 of the first side surface 600_S1 of the second molding layer 600 may be greater than a height H_600_S2 of the second side surface 600_S2 of the second molding layer 600. For example, the second molding layer 600 may fill the trench 510 of the first molding layer 500, and the height H_600_S1 of the first side surface 600_S1 of the second molding layer 600 may be greater than the height H_600_S2 of the second molding layer 600. In some embodiments, the height H_600_S1 of the first side surface 600_S1 of the second molding layer 600 may be greater than the height H_600_S2 of the second molding layer 600 by the extension depth of the trench 510.

In some embodiments, the height H_600_S1 of the first side surface 600_S1 of the second molding layer 600 may be greater than the height H_500_S1 of the first side surface 500_S1 of the first molding layer 500. Because a portion of the first side surface of the second molding layer 600 is inside the trench 510 of the first molding layer 500, the height H_600_S1 of the first side surface 600_S1 of the second molding layer 600 may be greater than the height H_500_S1 of the first side surface 500_S1 of the first molding layer 500.

In some embodiments, a sum of the height H_500_S1 of the first side surface 500_S1 of the first molding layer 500 and the height H_600_S1 of the first side surface 600_S1 of the second molding layer 600 may be substantially the same as a sum of the height H_500_S2 of the second side surface 500_S2 of the first molding layer 500 and the height H_600_S2 of the second side surface 600_S2 of the second molding layer 600. Because a portion of the first side surface 600_S1 of the second molding layer 600 is arranged inside the trench 510 of the first molding layer 500, as a result, the difference between the height H_500_S1 of the first side surface 500_S1 of the first molding layer 500 and the height H_500_S2 of the second side surface 500_S2 of the first molding layer 500 may be substantially the same as the difference between the height H_600_S1 of the first side surface 600_S1 of the second molding layer 600 and the height H_600_S2 of the second side surface 600_S2 of the second molding layer 600.

In some embodiments, an upper surface 600_U of the second molding layer 600 may be coplanar with an upper surface 400_U of the dummy chip 400. In other words, a vertical level of the upper surface 600_U of the second molding layer 600 may be substantially the same as a vertical level of the upper surface 400_U of the dummy chip 400.

In some embodiments, the first side surface 500_S1 of the first molding layer 500, the first side surface 600_S1 of the second molding layer 600, and the side surface of the first semiconductor chip 100 that are exposed to the outside of the semiconductor package 1000 may be coplanar with each other. In some embodiments, when the horizontal area W_400 of the dummy chip 400 is the same as the horizontal area W_200 of each of the plurality of second semiconductor chips 200, the second side surface 500_S2 of the first molding layer 500 may be coplanar with the second side surface 600_S2 of the second molding layer 600.

Referring again to FIG. 1, a package redistribution layer 700 is described.

The semiconductor package 1000 may further include the package redistribution layer 700 arranged under the lower surface of the first semiconductor chip 100. The package redistribution layer 700 may include a plurality of package redistribution line patterns 720, a plurality of package redistribution vias 740, and a package redistribution insulating layer 760. In some embodiments, the package redistribution insulating layer 760 may be stacked in plural.

The package redistribution insulating layer 760 may be formed by using, for example, a photo imageable dielectric (PID) material or a photosensitive polyimide (PSPI) material. For example, the package redistribution line pattern 720 and the plurality of package redistribution vias 740 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof but embodiments are not limited thereto. In some embodiments, the plurality of package redistribution line patterns 720 and the plurality of package redistribution vias 740 may be formed by stacking a metal or an alloy of a metal on a seed layer including Ti, titanium nitride, or titanium tungsten.

The plurality of package redistribution line patterns 720 may be arranged on at least one of an upper surface and a lower surface of the package redistribution insulating layer 760. Each of the plurality of package redistribution vias 740 may penetrate the package redistribution insulating layer 760, and may contact and be connected to some of the plurality of package redistribution line patterns 720. In some embodiments, at least some of the plurality of package redistribution line patterns 720 may be formed in one body together with some of the plurality of package redistribution vias 740. For example, the package redistribution line pattern 720 and the package redistribution via 740 in contact with an upper surface of the package redistribution line pattern 720 may be integrated in one body. The package redistribution insulating layer 760 may surround the plurality of package redistribution line patterns 720 and the plurality of package redistribution vias 740.

The plurality of package redistribution line patterns 720 and the plurality of package redistribution vias 740 may be electrically connected to the plurality of chip pads 150. In some embodiments, at least some of the plurality of package redistribution vias 740 may be in contact with the plurality of chip pads 150. For example, when the plurality of package redistribution insulating layers 760, in which the package redistributions 700 are stacked, is included, the package redistribution via 740 penetrating the package redistribution insulating layer 760 at the uppermost end may contact and be electrically connected to the plurality of chip pads 150.

In some embodiments, the plurality of package redistribution vias 740 may have a tapered shape, in which a horizontal width decreases and extends from a lower side to an upper side of the plurality of package redistribution vias 740. In other words, the plurality of package redistribution vias 740 may have greater horizontal widths away from the first semiconductor chip 100.

Among the plurality of package redistribution line patterns 720, the package redistribution line pattern 720 arranged on the lower surface of the package redistribution layer 700 may be referred to as a package pad 750. A plurality of package connection terminals 800 may be respectively attached to the plurality of package pads 750. For example, the package connection terminal 800 may include a solder ball or a bump.

In some embodiments, the semiconductor package 1000 may omit the package redistribution layer 700. For example, in some embodiments, the plurality of package connection terminals 800 may be attached to the plurality of chip pads 150.

A horizontal width and a horizontal area of the package redistribution layer 700 may be the same as the horizontal width and the horizontal area of the first semiconductor chip 100. The package redistribution layer 700 may overlap the first semiconductor chip 100 in the vertical direction D2.

FIGS. 4 through 6 are enlarged cross-sectional views of region II in FIG. 1 of semiconductor packages 1000a, 1000b, and 1000c, respectively, according to some embodiments.

The semiconductor packages 1000a, 100b, and 1000c of FIGS. 4 through 6 may be substantially the same as the semiconductor package 1000 of FIG. 2, except for shapes of trenches 510a, 510b, and 510c, respectively. Therefore, repeated description will be omitted for conciseness. Hereinafter, the shapes of the trenches 510a, 510b, and 510c are described in detail with reference to FIGS. 4 through 6.

As illustrated in FIG. 4, a first molding layer 500a of the semiconductor package 1000a may include the trench 510a. The trench 510a may be on a boundary of the first molding layer 500a, and may extend from an upper surface to the inside of the first molding layer 500a. In other words, the trench 510a may extend from the upper surface of the first molding layer 500a into the first molding layer 500a. A surface 510a_S forming the trench 510a may extend from an uppermost surface 500a_U of the first molding layer 500a to a first side surface 500a_S1 of the first molding layer 500a. The trench 510a may have a constant horizontal width even when the trench 510a is adjacent to the first semiconductor chip 100, i.e., may extend downwardly. In other words, the trench 510a may extend inwardly from the uppermost surface 500a_U of the first molding layer 500a without a change in the horizontal width of the trench 510a. The trench 510a may have a rectangular shape.

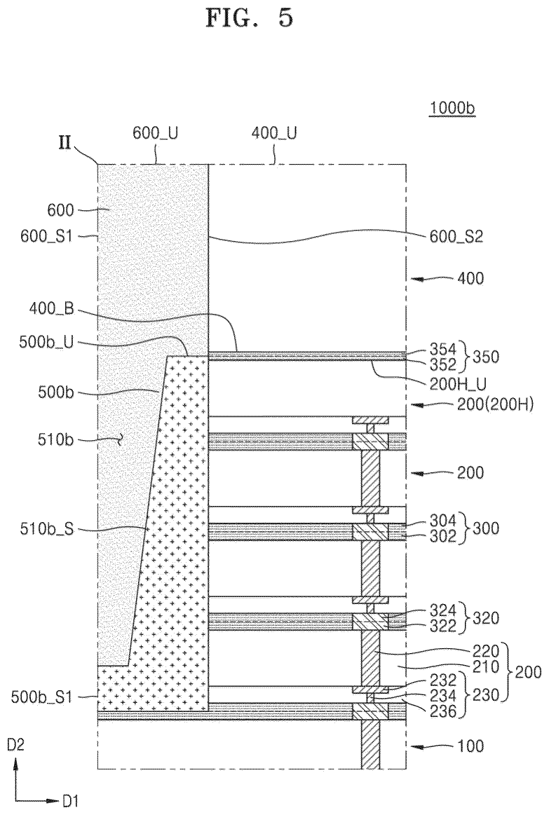

As illustrated in FIG. 5, a first molding layer 500b of the semiconductor package 1000b may include the trench 510b. The trench 510b may be on a boundary of the first molding layer 500b, and may extend from an upper surface to the inside of the first molding layer 500b. In other words, the trench 510b may extend from the upper surface of the first molding layer 500b into the first molding layer 500b. A surface 510b_S forming the trench 510b may extend from an uppermost surface 500b_U of the first molding layer 500b to a first side surface 500b_S1 of the first molding layer 500b. A horizontal width of the trench 510b may decrease toward the first semiconductor chip 100. For example, the surface 510b_S forming the trench 510b may include an inclined surface having a constant slope. The trench 510b may have a trapezoidal shape.

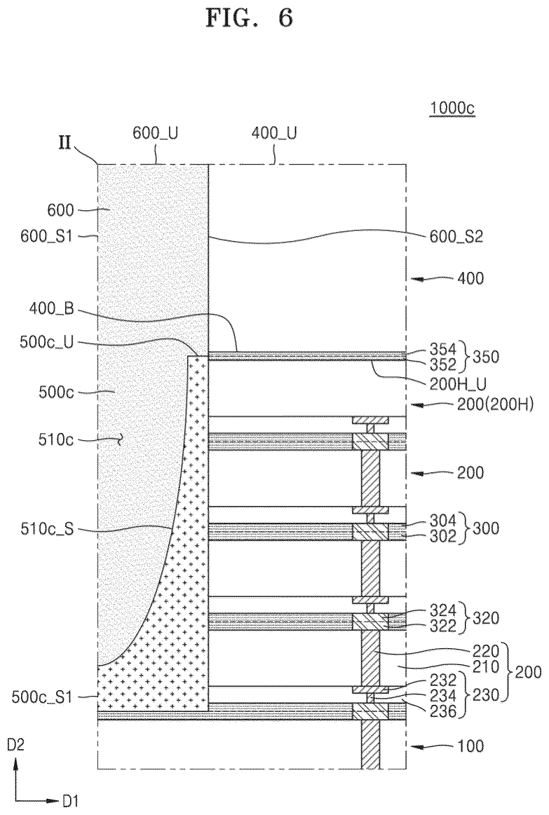

As illustrated in FIG. 6, a first molding layer 500c of the semiconductor package 1000c may include the trench 510c. The trench 510c may be on a boundary of an upper surface of the first molding layer 500c, and may extend from an upper surface to the inside of the first molding layer 500c. In other words, the trench 510c may extend from the upper surface of the first molding layer 500c into the first molding layer 500c. A surface 510c_S forming the trench 510c may extend from an uppermost surface 500c_U of the first molding layer 500c to a first side surface 500c_S1 of the first molding layer 500c. The surface 510c_S forming the trench 510c may have a curved surface, and a horizontal width of the trench 510c may decrease toward the first semiconductor chip 100. A surface 510c_S forming the trench 510c may extend as a curved surface from an uppermost surface 500c_U of the first molding layer 500c to the first side surface 500c_S1 of the first molding layer 500c.

However, the shape of the trench (500 in FIG. 2) included in the semiconductor package (1000 in FIG. 2) is not limited to those shapes illustrated in FIGS. 2 and 4 through 6, and various modifications and changes may be made within the scope of the technical concept.

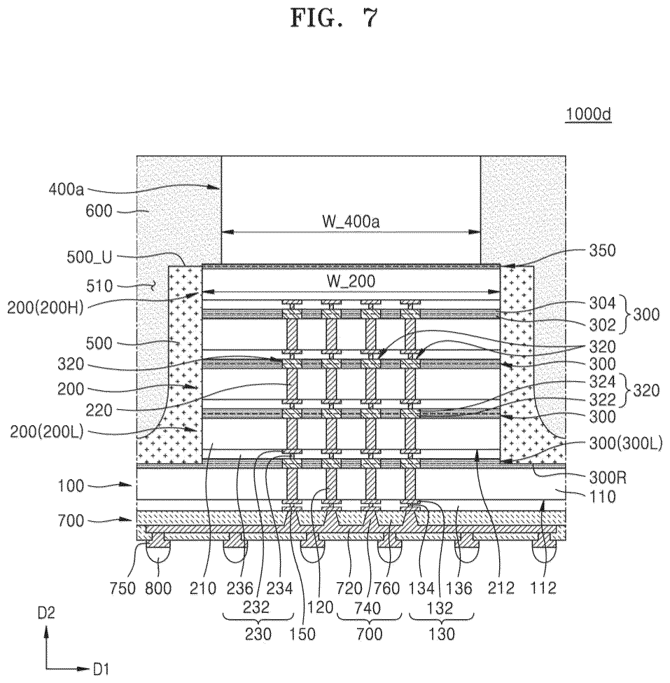

FIG. 7 is a schematic cross-sectional view of a semiconductor package 1000d according to an embodiment.

The semiconductor package 1000d of FIG. 7 may be substantially the same as the semiconductor package 1000 of FIG. 1, except for the difference in a dummy chip 400a. Therefore, repeated descriptions are omitted for conciseness. Hereinafter, the dummy chip 400a is described in detail with reference to FIG. 7.

In some embodiments, a horizontal area W_400a of the dummy chip 400a may be less than the horizontal area W_200 of each of the plurality of second semiconductor chips 200. For example, the length of the dummy chip 400 in the horizontal direction D1, i.e., the horizontal width thereof, may be less than the horizontal width of the uppermost second semiconductor chip 200H. The dummy chip 400a may be stacked on the upper surface of the uppermost second semiconductor chip 200H so that a center of an upper surface of the dummy chip 400a in the horizontal direction D1 matches a center of the plurality of second semiconductor chips 200 in the horizontal direction D1. Because the horizontal area W_400a of the dummy chip 400a is less than the horizontal area W_200 of each of the plurality of second semiconductor chips 200, the dummy chip 400a may cover a portion of the uppermost second semiconductor chip 200H.

In some embodiments, the support bonding insulating layer 350 may have a recess in an upper portion so that a thickness of a portion of the support bonding insulating layer 350 overlapping the dummy chip 400a in the vertical direction D2 is greater than a thickness of a portion thereof not overlapping the dummy chip 400a in the vertical direction D2. In other words, a recess may be arranged at a portion of the support bonding insulating layer 350 does not overlap the dummy chip 400a in the vertical direction D2.

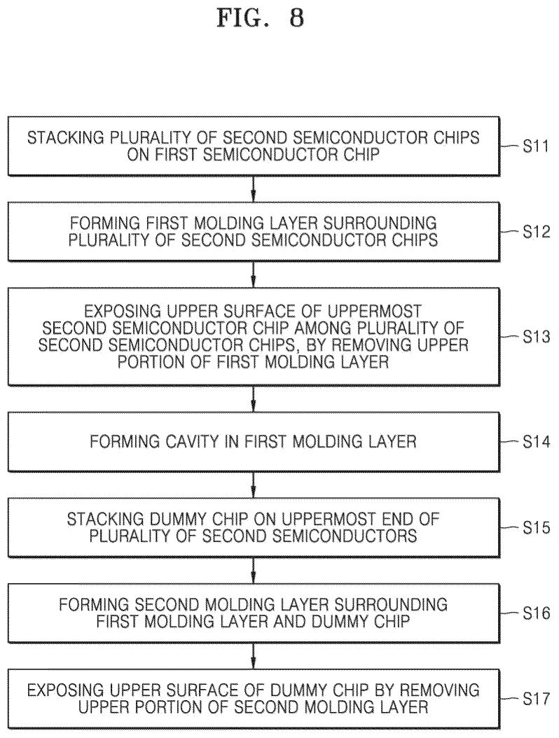

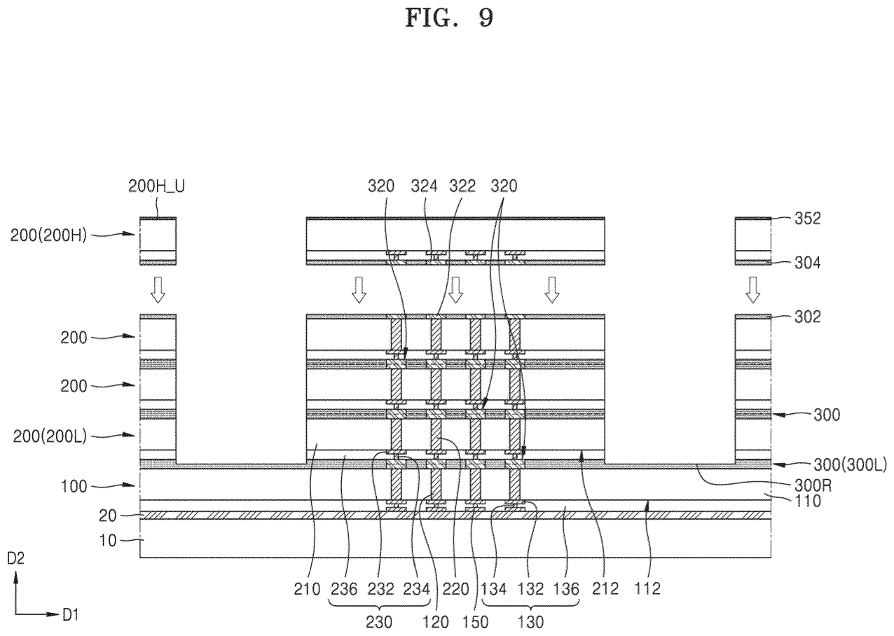

FIG. 8 is a flowchart of a manufacturing method of a semiconductor package, according to an embodiment. FIGS. 9 through 19 are cross-sectional views illustrating a manufacturing method of a semiconductor package according to a process sequence, according to some embodiments.

Referring to FIG. 8, a manufacturing method of a semiconductor package may include stacking a plurality of second semiconductor chips on a first semiconductor chip (S11), forming a first molding layer to surround the plurality of second semiconductor chips (S12), exposing an upper surface of an uppermost second semiconductor chip of among the plurality of second semiconductor chips by removing an upper portion of the first molding layer (S13), forming a cavity in the first molding layer (S14), stacking a dummy chip on the uppermost second semiconductor chip (S15), forming a second molding layer surrounding the first molding layer and the dummy chip (S16), and exposing an upper surface of the dummy chip by removing an upper portion of the second molding layer (S17).

Hereinafter, the manufacturing method of a semiconductor chip of FIG. 8 is described in detail with reference to FIGS. 9 through 19.

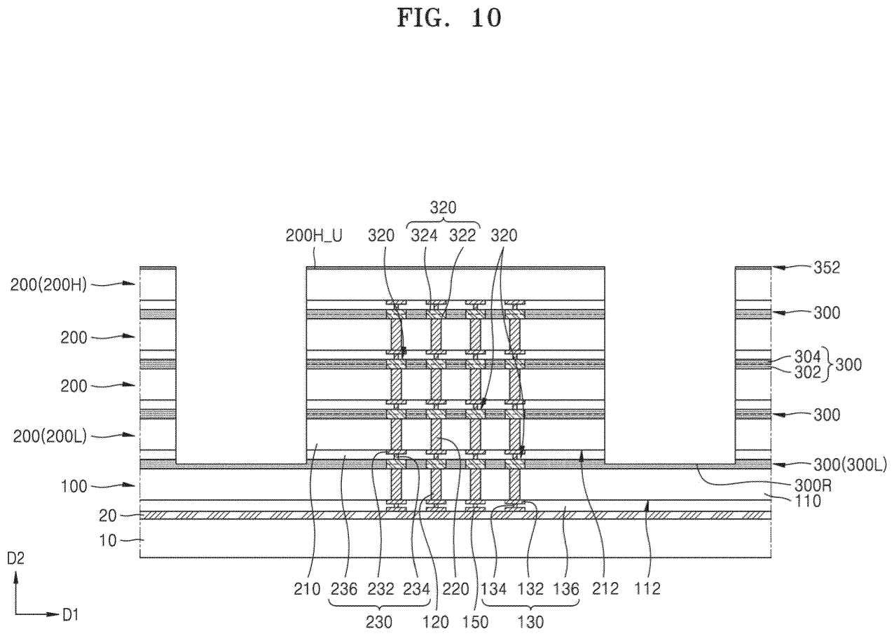

Referring to FIGS. 9 and 10, the first semiconductor chip 100 may be attached onto a support substrate 10. In some embodiments, the first semiconductor chip 100 may be attached to an upper surface of the support substrate 10 by using a release film 20. The first semiconductor chip 100 may be attached to the release film 20 so that the first distribution structure 130 faces the support substrate 10.

Next, the plurality of second semiconductor chips 200 may be stacked on the first semiconductor chip 100. The plurality of second semiconductor chips 200 may be stacked while overlapping each other in the vertical direction D2. The plurality of bonding pads 320 and the chip bonding insulating layer 300 may be arranged between the first semiconductor chip 100 and the lowermost second semiconductor chip 200L, and between each of the plurality of second semiconductor chips 200.

After the plurality of upper surface chip connection pads 322 and the plurality of lower surface chip connection pads 324 are respectively formed on surfaces facing each other of two adjacent chips among the first semiconductor chip 100 and the plurality of second semiconductor chips 200, each of the plurality of bonding pads 320 may be formed by diffusion bonding, in which the upper surface chip connection pad 322 and the lower surface chip connection pad 324 facing each other are expanded due to heat, and become one body, through diffusion of metal atoms which contact each other and are included therein.

After the upper surface chip bonding insulating material layer 302 and the lower surface chip bonding insulating material layer 304 are respectively formed on surfaces facing each other of two adjacent chips among the first semiconductor chip 100 and the plurality of second semiconductor chips 200, the chip bonding insulating layer 300 may be formed, in a process of forming the plurality of bonding pads 320, by diffusion bonding in which the upper surface chip bonding insulating material layer 302 and the lower surface chip bonding insulating material layer 304 facing each other are expanded due to heat, and become one body, through diffusion of atoms which contact each other and are included therein.

The plurality of second semiconductor chips 200 may be spaced apart from each other in the horizontal direction D1 and stacked on the first semiconductor chip 100. The lowermost chip bonding insulating layer 300L may have the first recess 300R in an upper portion thereof, so that the thickness of a portion thereof overlapping the plurality of second semiconductor chips 200 in the vertical direction D2 is greater than the thickness of a portion thereof not overlapping the plurality of second semiconductor chips 200 in the vertical direction D2.

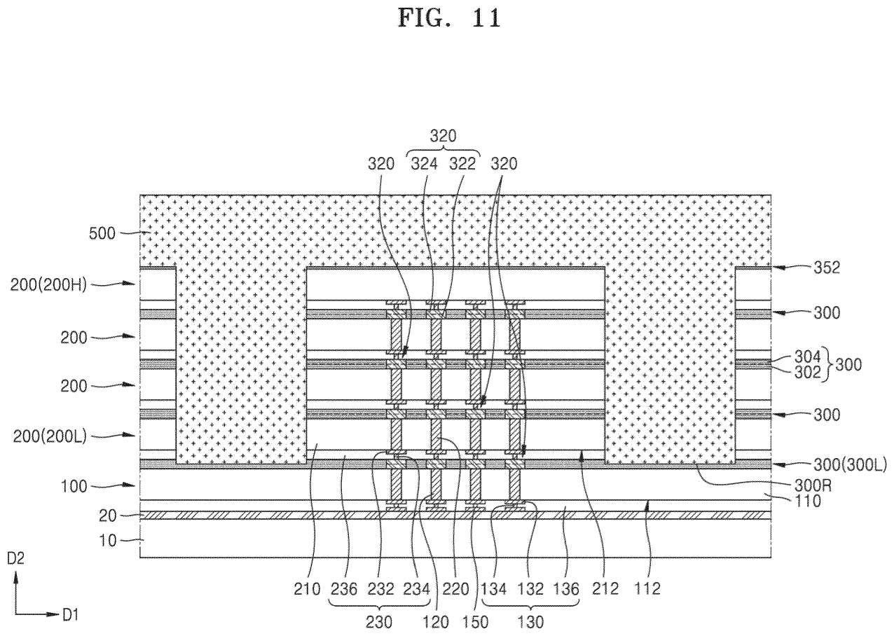

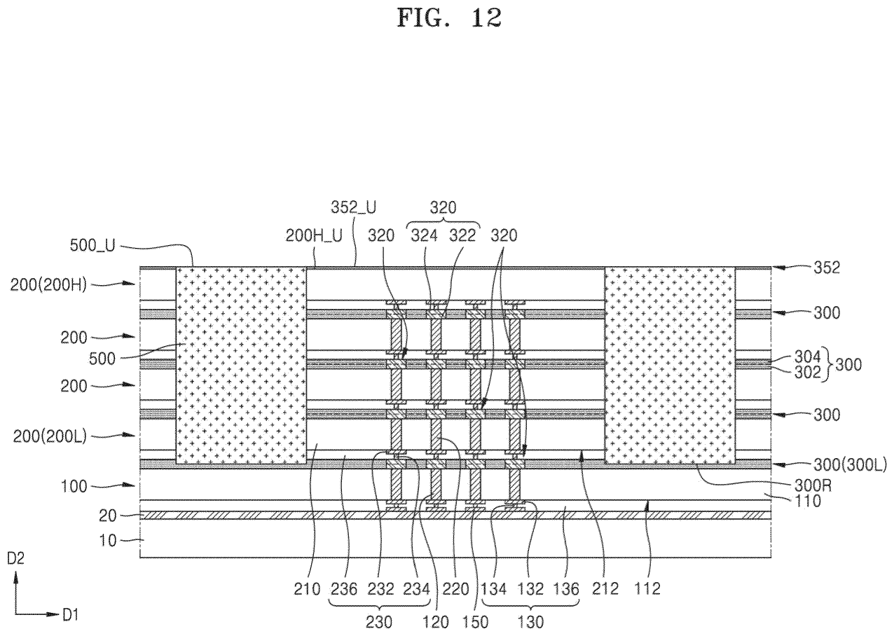

Referring to FIGS. 11 and 12, the first molding layer 500 may be formed to surround a portion of the upper surface of the first semiconductor chip 100 and the plurality of second semiconductor chips 200. Hereinafter, the upper portion of the first molding layer 500 may be removed to expose the upper surface 200H_U of the uppermost second semiconductor chip 200H. In some embodiments, an upper portion of the first molding layer 500 may be removed by using a CMP process.

In the process of stacking the plurality of second semiconductor chips 200 to overlap each other in the vertical direction D2, the surface roughness of the upper surfaces of the plurality of second semiconductor chips 200 may increase. Because the thickness of each of the plurality of second semiconductor chips 200 is small, and because during a stacking process, an unevenness occurs on the plurality of second semiconductor chips 200, the surface roughness of the upper surface of each of the plurality of second semiconductor chips 200 may increase. The unevenness may be greatest on the upper surface 200H_U of the uppermost second semiconductor chip 200H.

In the process of removing the upper portion of the first molding layer 500, the upper portion of the uppermost second semiconductor chip 200H may also be partially removed, and the surface roughness of the upper surface 200H_U of the uppermost second semiconductor chip 200H may be reduced. In some embodiments, the surface roughness of the upper surface 200H_U of the uppermost second semiconductor chip 200H may be 5 nm. In some embodiments, when the upper surface chip bonding insulating material layer 352 is included on the upper surface of the uppermost second semiconductor chip 200H, a portion of the upper surface chip bonding insulating material layer 352 may be removed in a CMP process, and the surface roughness of an upper surface 352_U of the upper surface chip bonding insulating material layer 352 may be reduced.

When the upper portion of the first molding layer 500 is removed, the uppermost surface 500_U of the first molding layer 500 may be coplanar with the upper surface 200H_U of the uppermost second semiconductor chip 200H. In some embodiments, when the upper surface chip bonding insulating material layer 352 is arranged on the upper surface 200H_U of the uppermost second semiconductor chip 200H, the uppermost surface 500_U of the first molding layer 500 may be coplanar with the upper surface 352_U of the upper surface chip bonding insulating material layer 352. In other words, the upper portion of the first molding layer 500 may be removed, until the uppermost surface 500_U of the first molding layer 500 is coplanar with the upper surface 200H_U of the uppermost second semiconductor chip 200H or the uppermost surface 500_U of the first molding layer 500 is coplanar with the upper surface chip bonding insulating material layer 352.

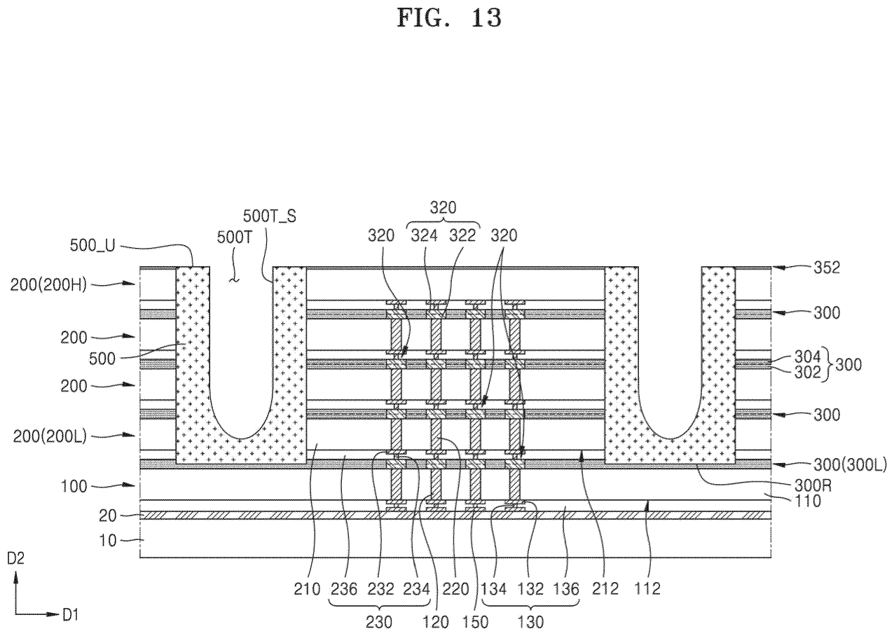

Referring to FIG. 13, a cavity 500T may be formed in the first molding layer 500. The cavity 500T may be formed to extend from the uppermost surface 500_U to the inside of the first molding layer 500. In other words, the cavity 500T may extend from the uppermost surface 500_U into the first molding layer 500. In some embodiments, the cavity 500T may be formed by using a blade cutting method. Accordingly, the surface roughness of a surface 500T_S forming the cavity 500T may be greater than the surface roughness of the upper surface 200H_U of the uppermost second semiconductor chip 200H.

In some embodiments, a horizontal width of the cavity 500T may be constant. In some embodiments, the cavity 500T may have a shape in which the horizontal width is constant at an upper portion and is reduced at a lower portion thereof. In some embodiments, the cavity 500T may have a shape in which the horizontal width thereof decreases toward the first semiconductor chip 100. However, the shape of the cavity 500T may be varied depending on a method of removing the first molding layer 500.

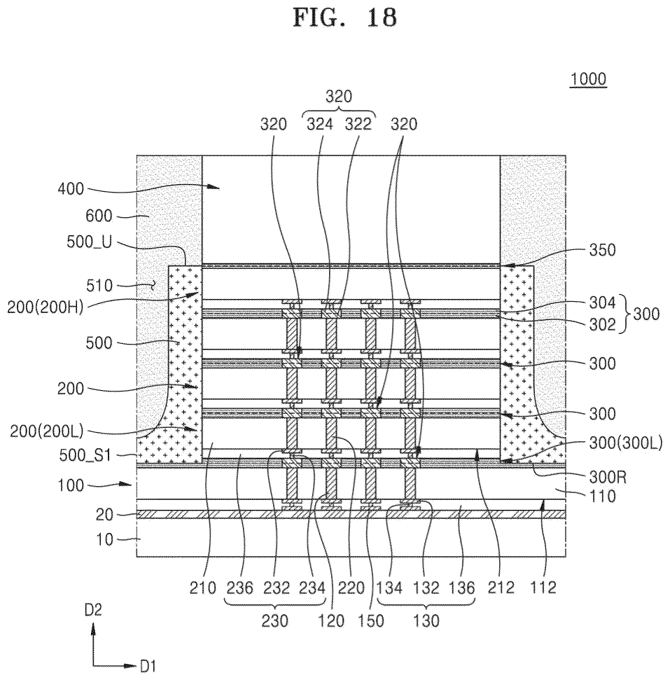

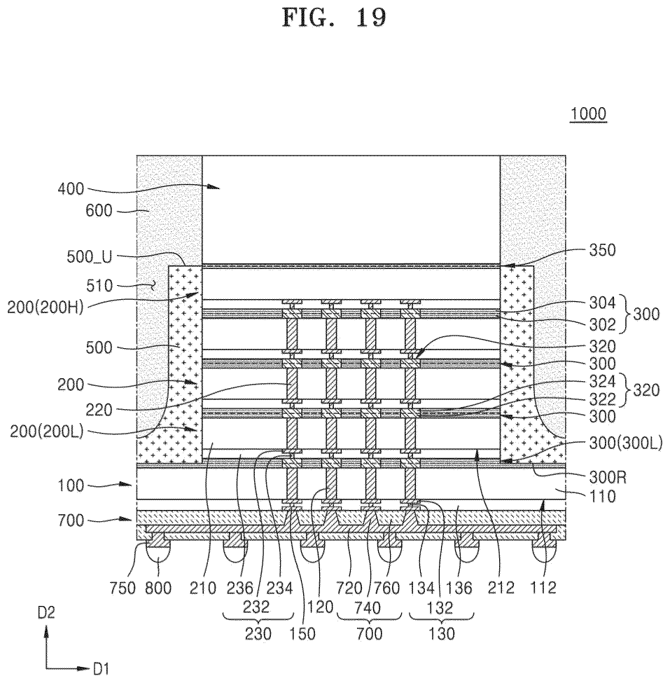

In a subsequent process, described later, of separating the plurality of second semiconductor chips 200 from each other in the horizontal direction D1 (see, e.g., FIGS. 18-19), the cavity 500T of the first molding layer 500 may be divided into two, and each of which may become the trench 510 described above. The shape of the trench 510 may vary depending on the shape of the cavity 500T.

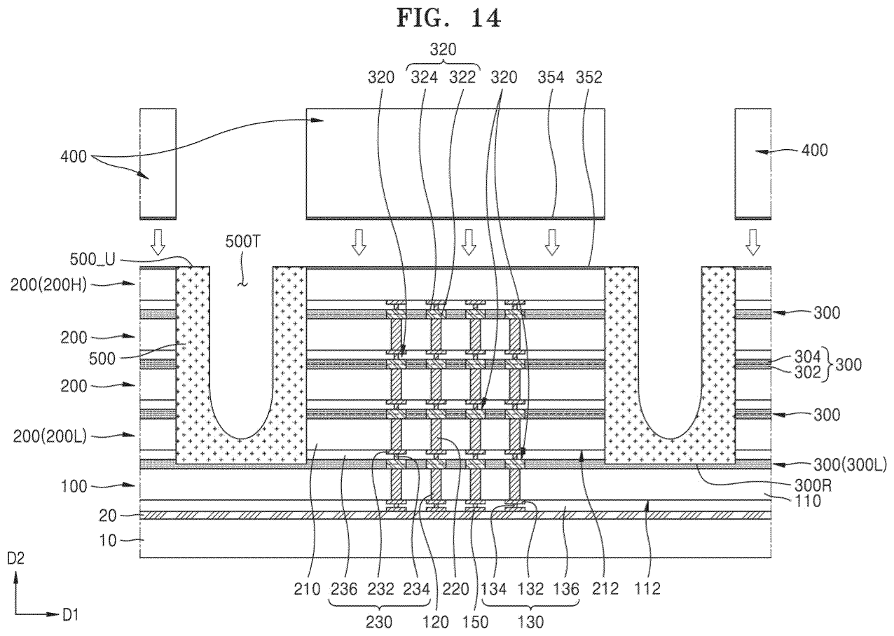

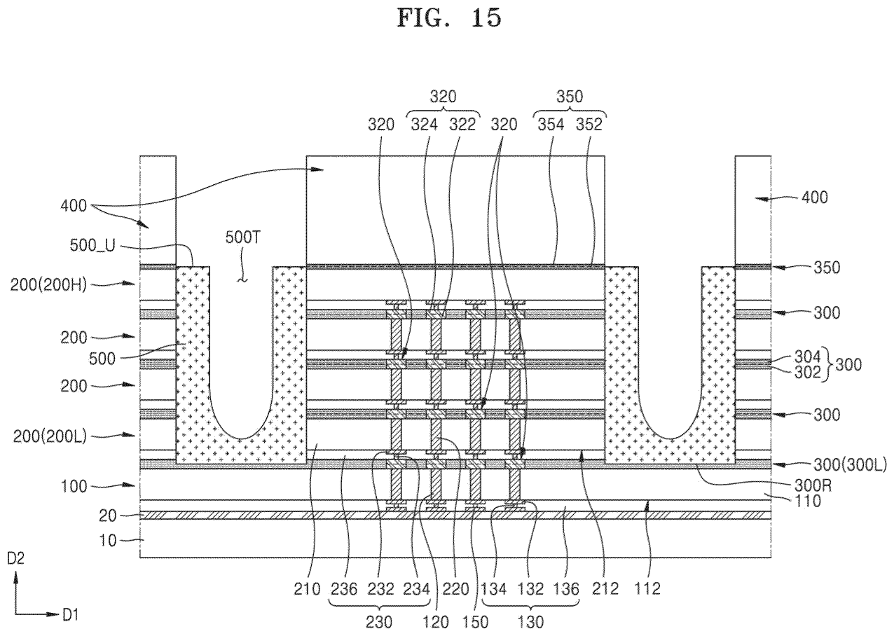

Referring to FIGS. 14 and 15, the dummy chip 400 may be stacked on the uppermost second semiconductor chip 200H of the plurality of second semiconductor chips 200. The support bonding insulating layer 350 may be arranged between the uppermost second semiconductor chip 200H and the dummy chip 400.

The support bonding insulating layer 350 may be formed, after the upper surface chip bonding insulating material layer 352 on the upper surface of the uppermost second semiconductor chip 200H and the lower surface dummy bonding insulating material layer 354 on the lower surface 400_B of the dummy chip 400 are expanded due to heat, and become one body, through diffusion of atoms which contact each other and are included therein. In some embodiments, the uppermost second semiconductor chip 200H and the dummy chip 400 may be bonded only by using the support bonding insulating layer 350.

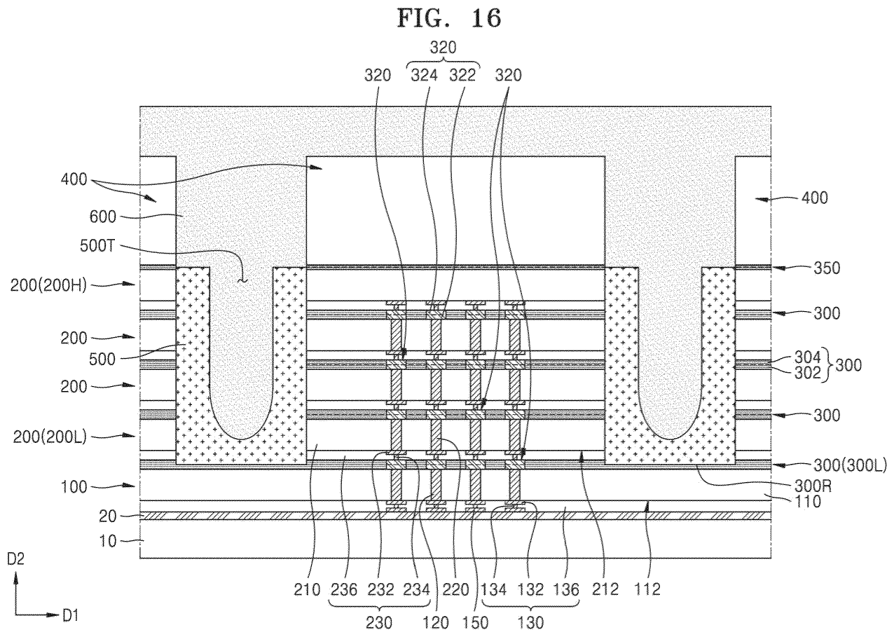

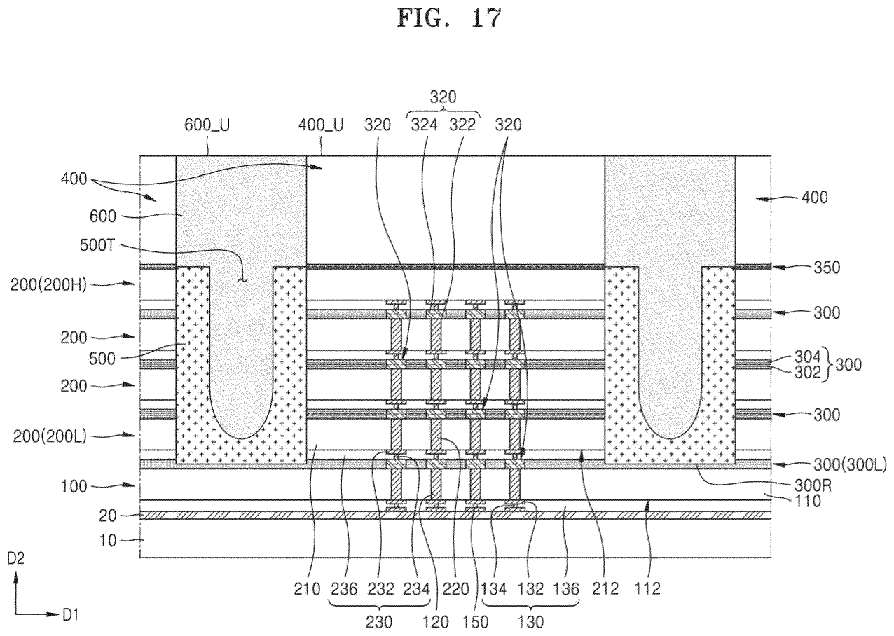

Referring to FIGS. 16 and 17, the second molding layer 600 may be formed to surround the first molding layer 500 and the dummy chip 400. The second molding layer 600 may be formed to surround the first molding layer 500 and the dummy chip 400 while filling the cavity 500T of the first molding layer 500.

Thereafter, the upper portion of the second molding layer 600 may be removed so that the upper surface of the dummy chip 400 is exposed. In some embodiments, the upper portion of the second molding layer 600 may be removed by using a CMP process. The upper surface 600_U of the second molding layer 600 may be coplanar with the upper surface 400_U of the dummy chip 400. In other words, a vertical level of the upper surface 600_U of the second molding layer 600 may be substantially the same as a vertical level of the upper surface 400_U of the dummy chip 400.

Referring to FIGS. 18 and 19, the plurality of second semiconductor chips 200 that are spaced apart from each other in the horizontal direction D1 may be separated based on the cavity 500T. Thereafter, the support substrate 10 and the release film 20 may be separated from the first semiconductor chip 100, and the package redistribution layer 700 may be formed under the first semiconductor chip 100.

In the process of separating the plurality of second semiconductor chips 200 based on the cavity 500T, one cavity 500T may be separated and become two trenches 510 located on different first molding layers 500. The trench 510 may be at an edge of the first molding layer 500. The side surface of the first semiconductor chip 100 exposed to the outside, the first side surface 500_S1 of the first molding layer 500, and the side surface exposed to the outside of the second molding layer 600 may be coplanar with each other. In some embodiments, the trench 510 may include the trench described above (510 in FIG. 2, 510a in FIG. 4, 510b in FIG. 5, or 510c in FIG. 6).

The package redistribution layer 700 may include the plurality of package redistribution line patterns 720, the plurality of package redistribution vias 740, and the package redistribution insulating layer 760. In some embodiments, the package redistribution insulating layer 760 may be stacked in plural.

Among the plurality of package redistribution line patterns 720, the package redistribution line pattern 720 arranged on the lower surface of the package redistribution layer 700 may be referred to as the package pad 750. The plurality of package connection terminals 800 may be respectively attached to the plurality of package pads 750. For example, the package connection terminal 800 may include a solder ball or a bump.

In some embodiments, the semiconductor package 1000 may omit the package redistribution layer 700. For example, the plurality of package connection terminals 800 may be attached to the plurality of chip pads 150.

While various embodiments have been particularly shown and described with reference to the drawings, it will be understood that various changes in form and details may be made therein without departing from the spirit and scope of the following claims.

What is claimed is:

1. A semiconductor package comprising:
a first semiconductor chip;
a plurality of second semiconductor chips stacked on the first semiconductor chip, each of the plurality of second semiconductor chips including a semiconductor substrate comprising an active surface and an inactive surface opposite to the active surface;
a first molding layer surrounding a portion of an upper surface of the first semiconductor chip and side surfaces of the plurality of second semiconductor chips, the first molding layer including a trench that extends from an upper surface of the first molding layer into the first molding layer;
a dummy chip stacked on an uppermost second semiconductor chip of the plurality of second semiconductor chips; and
a second molding layer surrounding side surfaces of the dummy chip, and covering the first molding layer.

2. The semiconductor package of claim 1,
wherein the trench extends from a corner of an uppermost surface of the first molding layer to a corner of a side surface of the first molding layer that is exposed to the outside of the semiconductor package, and
wherein the second molding layer fills the trench.

3. The semiconductor package of claim 2, wherein the trench comprises a curved surface portion in which an internal horizontal width of the trench decreases toward the first semiconductor chip.

4. The semiconductor package of claim 2,
wherein the second molding layer is spaced apart from the first semiconductor chip in a vertical direction with the first molding layer therebetween, and
the second molding layer is spaced apart from the plurality of second semiconductor chips in a horizontal direction with the first molding layer therebetween.

5. The semiconductor package of claim 1, wherein a horizontal length of an uppermost surface of the first molding layer is less than a horizontal length of a lower surface of the first molding layer.

6. The semiconductor package of claim 1, wherein a vertical length of a side surface of the first molding layer that is in contact with the plurality of second semiconductor chips among side surfaces of the first molding layer is greater than a vertical length of a side surface of the first molding layer that is exposed to the outside of the semiconductor package among the side surfaces of the first molding layer.

7. The semiconductor package of claim 1, wherein a vertical length of a side surface of the second molding layer that is in contact with the dummy chip among side surfaces of the second molding layer is less than a vertical length of a side surface of the second molding layer that is exposed to the outside of the semiconductor package among the side surfaces of the second molding layer.

8. The semiconductor package of claim 1, wherein a vertical length of a side surface of the second molding layer that is exposed to the outside of the semiconductor package among side surfaces of the second molding layer is greater than a vertical length of a side surface of the first molding layer that is exposed to the outside of the semiconductor package among side surfaces of the first molding layer.

9. The semiconductor package of claim 1,
wherein a composition material of the first molding layer is identical to a composition material of the second molding layer, and
a boundary surface is between the first molding layer and the second molding layer.

10. The semiconductor package of claim 1,
wherein the uppermost second semiconductor chip among the plurality of second semiconductor chips further comprises a bonding insulating material layer on an upper surface of the uppermost second semiconductor chip, and
wherein an uppermost surface of the first molding layer is coplanar with the bonding insulating material layer.

11. The semiconductor package of claim 1, wherein a thickness of each of the plurality of second semiconductor chips is less than a thickness of the dummy chip.

12. The semiconductor package of claim 11,
wherein a thickness of each of the plurality of second semiconductor chips is 20 μm to 80 μm, and
a thickness of the dummy chip is 100 μm to 500 μm.

13. The semiconductor package of claim 1, wherein a surface roughness of an upper surface of the uppermost second semiconductor chip among the plurality of second semiconductor chips is 0.1 nm to 6 nm.

14. The semiconductor package of claim 1, wherein a horizontal area of the dummy chip is equal to or less than a horizontal area of each of the plurality of second semiconductor chips.

15. A semiconductor package comprising:
a first semiconductor chip including a first semiconductor substrate comprising an active surface and an inactive surface opposite to the active surface;
a plurality of second semiconductor chips stacked on the first semiconductor chip, each of the plurality of second semiconductor chips including a second semiconductor substrate comprising an active surface and an inactive surface opposite to the active surface of the second semiconductor substrate;
a first molding layer surrounding a portion of an upper surface of the first semiconductor chip and side surfaces of the plurality of second semiconductor chips, the first molding layer including a trench that extends from an upper surface of the first molding layer into the first molding layer;
a dummy chip stacked on an uppermost second semiconductor chip among the plurality of second semiconductor chips; and
a second molding layer surrounding side surfaces of the dummy chip, filling the trench, and covering an upper surface of the first molding layer,
wherein the plurality of second semiconductor chips are stacked with the active surface of the second semiconductor substrate of each of the plurality of second semiconductor chips facing the first semiconductor chip.

16. The semiconductor package of claim 15, further comprising a plurality of bonding pads and a plurality of chip bonding insulating layers,
wherein the plurality of bonding pads are arranged between adjacent ones of the plurality of second semiconductor chips, and electrically connect the plurality of second semiconductor chips to each other, and
wherein each of the plurality of chip bonding insulating layers surrounds the plurality of bonding pads and fills a remaining space between the adjacent ones of the plurality of second semiconductor chips.

17. The semiconductor package of claim 16, further comprising a support bonding insulating layer having a thickness that is less than a thickness of each of the plurality of chip bonding insulating layers,
wherein the support bonding insulating layer is arranged between the dummy chip and the uppermost second semiconductor chip among the plurality of second semiconductor chips, and
wherein the uppermost second semiconductor chip is connected to the dummy chip only by the support bonding insulating layer.

18. The semiconductor package of claim 17, wherein a vertical level of an uppermost surface of the first molding layer is lower than a vertical level of an upper surface of the support bonding insulating layer, and higher than a vertical level of a lower surface of the support bonding insulating layer.

19. A semiconductor package comprising:
a first semiconductor chip including a first semiconductor substrate comprising an active surface and an inactive surface opposite to the active surface, and a plurality of first through electrodes configured to penetrate the first semiconductor substrate;
a plurality of second semiconductor chips stacked on the first semiconductor chip, each of the plurality of second semiconductor chips including a second semiconductor substrate comprising an active surface and an inactive surface opposite to the active surface of the second semiconductor substrate;
a first molding layer including a trench that surrounds side surfaces of the plurality of second semiconductor chips and extends from an upper surface of the first molding layer into the first molding layer, the first molding layer including a first side surface and a second side surface opposite to the first side surface;
a dummy chip stacked on the plurality of second semiconductor chips, the dummy chip having a horizontal area identical to a horizontal area of each of the plurality of second semiconductor chips and having a height greater than a height of each of the plurality of second semiconductor chips;
a second molding layer surrounding side surfaces of the dummy chip, filling the trench, and covering the first molding layer;
a package redistribution layer under a lower surface of the first semiconductor chip; and
a plurality of package connection terminals electrically connected to the package redistribution layer,
wherein at least one of the plurality of second semiconductor chips comprises a plurality of second through electrodes configured to penetrate the second semiconductor substrate of the at least one of the plurality of second semiconductor chips,
wherein the trench is arranged at a periphery of an uppermost surface of the first molding layer,
wherein the first side surface of the first molding layer includes a side surface of the first molding layer that is exposed to an outside of the semiconductor package, and the second side surface of the first molding layer includes a side surface that is in contact with the plurality of second semiconductor chips, and
wherein a height of the first side surface of the first molding layer is less than a height of the second side surface of the first molding layer.

20. The semiconductor package of claim 19, further comprising a chip bonding insulating layer, a support bonding insulating layer, and a plurality of bonding pads,
wherein the plurality of bonding pads are arranged between adjacent ones of the plurality of second semiconductor chips, and electrically connect the plurality of second semiconductor chips to each other,
wherein the chip bonding insulating layer surrounds the plurality of bonding pads and fills remaining spaces between the adjacent ones of the plurality of second semiconductor chips,
wherein a mean roughness of an upper surface of an uppermost second semiconductor chip among the plurality of second semiconductor chips is 0.1 nm to 6 nm,
wherein the support bonding insulating layer is arranged between the uppermost second semiconductor chip and the dummy chip, and has a thickness that is less than a thickness of the chip bonding insulating layer, and
wherein a vertical level of the uppermost surface of the first molding layer is lower than a vertical level of an upper surface of the support bonding insulating layer, and higher than a vertical level of a lower surface of the support bonding insulating layer.
